(19) United States
(12) Patent Application Publication
(10) Pub. No.: US 2025/0153349 A1
(43) Pub. Date: May 15, 2025

(54) SUBSTRATE-CONVEYING ROBOT

(71) Applicant: KAWASAKI JUKOGYO KABUSHIKI KAISHA, Kobe-shi, Hyogo (JP)

(72) Inventors: Takeshi SHIBATA, Kobe-shi (JP); Ryota ONO, Kobe-shi (JP); Junichi MATSUOKA, Kobe-shi (JP)

(73) Assignee: KAWASAKI JUKOGYO KABUSHIKI KAISHA, Kobe-shi, Hyogo (JP)

(21) Appl. No.: 18/833,536

(22) PCT Filed: Dec. 7, 2022
(86) PCT No.: PCT/JP2022/045059

§ 371 Date: Jul. 26, 2024

(30) Foreign Application Priority Data
Feb. 4, 2022 (JP) 2022-016723

(51) Int. Cl. B25J 9/10; B25J 9/04; B25J 11/00; B25J 17/02

(52) U.S. Cl. CPC B25J 9/108; B25J 9/042; B25J 11/0095; B25J 17/02

(57) ABSTRACT

A substrate-conveying robot (100) includes a wrist joint (JT3) including a first bearing(s) (42) rotatably supporting a first rotation shaft (41) for rotating a first substrate-holding hand (21), and a second bearing(s) (44) rotatably supporting a second rotation shaft (43) for rotating the second substrate-holding hand (22). The first and second bearings are ball bearings.

### TECHNICAL FIELD

The present disclosure relates to a substrate-conveying robot.

### BACKGROUND ART

Substrate-conveying robots including a robot arm are known in the art. Such a substrate-conveying robot is disclosed in Japanese Patent Publication No. JP 6271266, for example.

The above Japanese Patent Publication No. JP 6271266 discloses a horizontal multi-joint robot for conveying a to-be-conveyed object such as a glass substrate. The robot includes an arm, and a hand rotatably connected to a distal end part of the arm. A connection part between the arm and the hand is a joint. A speed reducer and a bearing are arranged to rotate the hand in the joint. The bearing is a cross roller bearing.

### PRIOR ART

### Patent Document

Patent Document 1: Japanese Patent Publication No. JP 6271266

### SUMMARY OF THE INVENTION

However, in the robot described in the above Japanese Patent Publication No. JP 6271266, because the bearing is a cross roller bearing, rollers including cylindrical rolling elements have deflections in some cases. In such a case, when the robot repeatedly operates, the deflections of the rollers wobble in repeated operations so that the wobbling of the deflections of the rollers fluctuates friction of the bearing. Also, if the friction of the bearing fluctuates, fluctuation of the friction of the bearing fluctuates a rotation amount of the joint so that the fluctuation of the rotation amount of the joint fluctuates a position of each repeated operation. For this reason, in a case in which the cross roller bearing is used as a bearing, it is difficult to improve positioning accuracy of repeated operations.

The present disclosure is intended to solve the above problem, and one object of the present disclosure is to provide a substrate-conveying robot capable of improving positioning accuracy of repeated operations.

A substrate-conveying robot according to a first aspect of the present disclosure includes a horizontal multi-joint robot arm; and a substrate-holding hand arranged in a distal end part of the robot arm, wherein the substrate-holding hand includes a first substrate-holding hand, and a second substrate-holding hand arranged on or above the first substrate-holding hand and operating independently of the first substrate-holding hand, the robot arm includes a wrist joint for driving the first substrate-holding hand and the second substrate-holding hand, the wrist joint includes a first bearing(s) rotatably supporting a first rotation shaft for rotating the first substrate-holding hand, and a second bearing(s) rotatably supporting a second rotation shaft for rotating the second substrate-holding hand, and the first bearing(s) and the second bearing(s) are ball bearings.

In the substrate-conveying robot according to the first aspect of the present disclosure, as discussed above, the first bearing(s) and the second bearing(s) are ball bearings. According to this configuration, dissimilar to a case in which cross roller bearings are used as the first and second bearings, because spherical balls can be used as rolling elements instead of cylindrical rolling elements, it is possible to prevent that wobbling of deflections of the rollers causes fluctuation of friction of the bearings and fluctuation of a rotation amount of the wrist joint. Consequently, positioning accuracy of repeated operations can be improved by preventing fluctuation of a position of each repeated operation of the substrate-conveying robot.

A substrate-conveying robot according to a second aspect of the present disclosure includes a horizontal multi-joint robot arm; and a substrate-holding hand arranged in a distal end part of the robot arm, wherein the robot arm includes a first arm part, a second arm part including one end connected to the first arm part and another end to which the substrate-holding hand is connected, and an arm part joint for driving the second arm part, the arm part joint includes an arm part rotation shaft bearing(s) rotatably supporting an arm part rotation shaft for rotating the second arm part, and the arm part rotation shaft bearing(s) is/are arranged astride the first arm part and the second arm part in a height direction.

In the substrate-conveying robot according to a second aspect of the present disclosure, as discussed above, the arm part rotation shaft bearing(s) is/are arranged astride the first arm part and the second arm part in a height direction. According to this configuration, dissimilar to a case in which the arm part rotation shaft bearing(s) is/are arranged in the first arm part or the second arm part, because the first arm part or the second arm part does not necessarily have a height that can accommodate the entire arm part rotation shaft bearing(s), it is possible to reduce increase of a size of the first arm part or the second arm in the height direction. Consequently, it is possible to reduce increase of a size of the substrate-conveying robot in the height direction.

It is possible to improve positioning accuracy of repeated operations.

### BRIEF DESCRIPTION OF THE DRAWINGS

FIG. 1 is a diagram schematically showing a configuration of a substrate-conveying robot according to a first embodiment.

FIG. 2 is a cross-sectional view showing the configuration of the substrate-conveying robot according to the first embodiment.

FIG. 3 is an enlarged view of a first arm shown in FIG. 2.

FIG. 4 is an enlarged view of a second arm shown in FIG. 2.

FIG. 5 is a cross-sectional view showing a configuration of a substrate-conveying robot according to a second embodiment.

### MODES FOR CARRYING OUT THE INVENTION

Embodiments embodying the present disclosure will be described with reference to the drawings.

### (Configuration of Substrate-Conveying Robot)

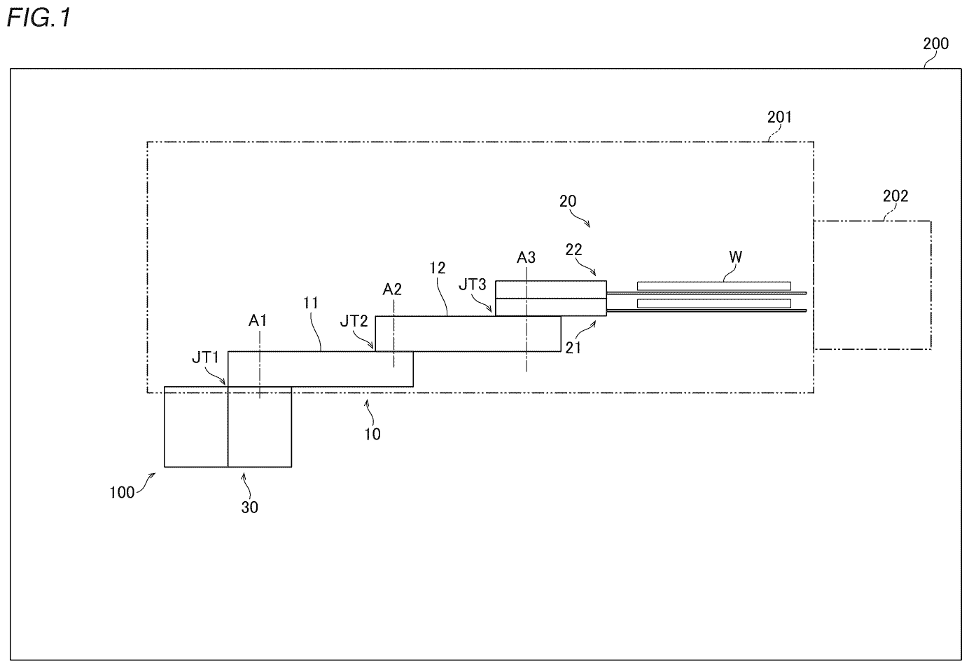

The following description describes a configuration of a substrate-conveying robot 100 according to a first embodiment with reference to FIGS. 1 to 4. As shown in FIG. 1, the substrate-conveying robot 100 is a robot for conveying substrates W. The substrate-conveying robot 100 is arranged in a clean room 200. Also, the substrate-conveying robot 100 is arranged in a vacuum environment. Specifically, the substrate-conveying robot 100 is arranged in a vacuum chamber 201.

The substrate-conveying robot 100 includes a robot arm 10, a substrate-holding hand 20 arranged in a distal end part of the robot arm 10, and a base 30. The substrate-holding hand 20 holds the substrates W. The substrates W are semiconductor wafers, for example. The semiconductor wafers are processed in a processing room 202. The substrate-conveying robot 100 performs repeated operations for repeatedly convey the semiconductor wafers to the processing room 202.

Also, the substrate-holding hand 20 includes a first substrate-holding hand 21, and a second substrate-holding hand 22 arranged above the first substrate-holding hand 21 and operating independently of the first substrate-holding hand 21.

The robot arm 10 is a horizontal multi-joint robot arm. The robot arm 10 includes a first arm part 11 and a second arm part 12. Also, the robot arm 10 includes a shoulder joint JT1, an elbow joint JT2 and a wrist joint JT3. One end of the first arm part 11 is connected to the base 30 through the shoulder joint JT1. One end of the second arm part 12 is connected to the other end of the first arm part 11 through the elbow joint JT2. The first substrate-holding hand 21 and the second substrate-holding hand 22 are connected another end of the second arm part 12 through the wrist joint JT3. The shoulder joint JT1 is an example of a first joint. The elbow joint JT2 is an example of a second joint and an example of an arm part joint.

The shoulder joint JT1 is provided to drive the first arm part 11. Specifically, the shoulder joint JT1 rotates the first arm part 11 relative to the base 30 about a first rotation axis A1, which extends in an upward/downward direction. The elbow joint JT2 is provided to drive the second arm part 12. Specifically, the elbow joint JT2 rotates the second arm part 12 relative to the first arm part 11 about a second rotation axis A2, which extends in the upward/downward direction. The wrist joint JT3 is provided to drive the first substrate-holding hand 21 and the second substrate-holding hand 22. Specifically, the wrist joint JT3 rotates the first substrate-holding hand 21 and the second substrate-holding hand 22 relative to the second arm part 12 about a third axis A3, which extends in the upward/downward direction. Here, the wrist joint JT3 can rotate the first substrate-holding hand 21 and the second substrate-holding hand 22 separately from each other. The shoulder joint JT1, the elbow joint JT2 and the wrist joint JT3 will be described in detail later.

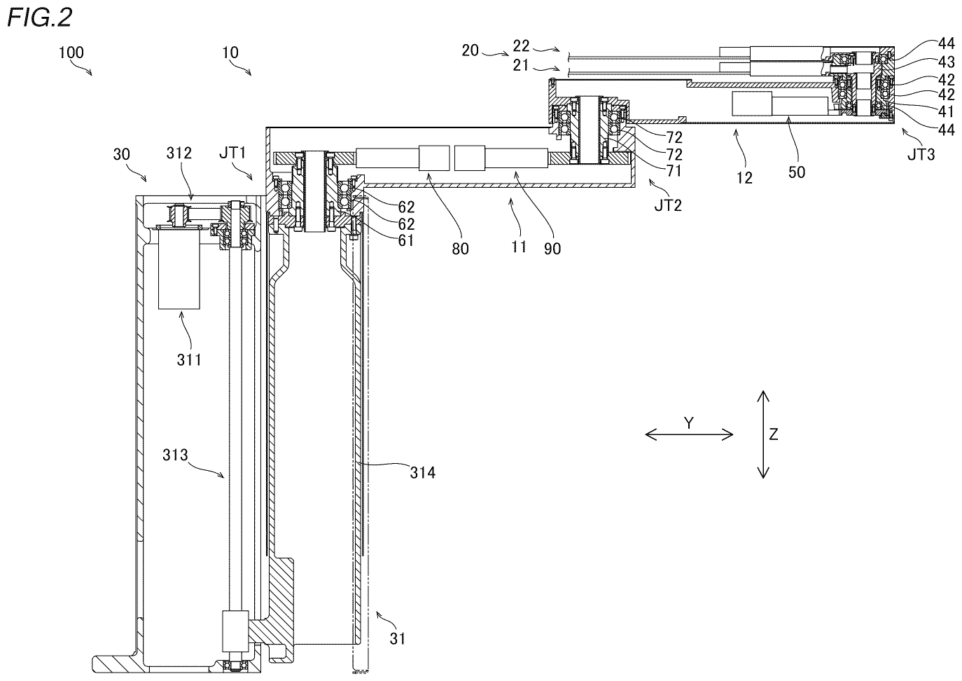

As shown in FIG. 2, the base 30 includes an upward/downward mover 31 for moving the robot arm 10 upward/downward. The upward/downward mover 31 includes an electric motor 311, a belt pulley mechanism 312, a ball screw mechanism 313, and a torque tube 314. The electric motor 311 is a driving source for upward/downward movement. The electric motor 311 is connected to the ball screw mechanism 313 through the belt pulley mechanism 312. The ball screw mechanism 313 is connected to the torque tube 314, and moves the torque tube 314 upward/downward by using a driving force from the electric motor 311. The torque tube 314 is connected to one end part of the first arm part 11 of the robot arm 10, and moves the robot arm 10 upward/downward by using a driving force from the ball screw mechanism 313 through the first arm part 11.

### (Wrist Joint)

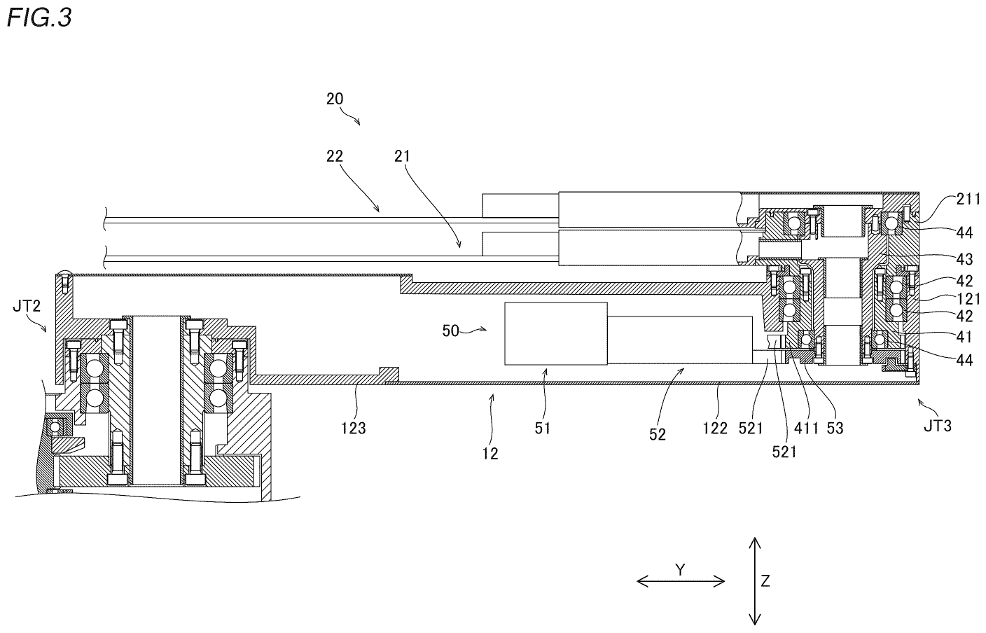

Here, in the first embodiment, as shown in FIGS. 2 and 3, the wrist joint JT3 includes first bearings 42 rotatably supporting a first rotation shaft 41 for rotating the first substrate-holding hand 21, and second bearings 44 rotatably supporting a second rotation shaft 43 for rotating the second substrate-holding hand 22. The first bearing 42 and the second bearing 44 are ball bearings. Specifically, the first bearings 42 are two angular contact ball bearings, and the second bearings 44 are two angular contact ball bearings. Each of the first bearings 42 and the second bearings 44 includes balls as rolling elements, a retainer retaining the balls, an outer race, and an inner race. The balls are retained in the retainer to be positioned without deflection.

Also, in the first embodiment, the second rotation shaft 43 is arranged inward of the first rotation shaft 41 in a radial direction, and extends upward with respect to the first rotation shaft 41. The two second bearings 44 are arranged in upper and lower parts of the second rotation shaft 43. The two second bearings 44 are spaced away from each other in a Z direction, which is a height direction. In the two second bearings 44, the upper second bearing 44 bears an axial load in one axial direction, and the lower second bearing 44 bears an axial load in another axial direction. Also, the upper second bearing 44 is arranged between a housing part 211 of the first substrate-holding hand 21 and the second rotation shaft 43 in a radial direction. Also, the lower second bearing 44 is arranged between the first rotation shaft 41 and the second rotation shaft 43 in the radial direction.

Also, the two first bearings 42 are arranged on the first rotation shaft 41 between the two second bearings 44. The two first bearings 42 are arranged adjacent to each other in the Z direction, which is the height direction. In the two first bearings 42, the upper first bearing 42 bears an axial load in one axial direction, and the lower first bearing 42 bears an axial load in another axial direction. Also, the two first bearings 42 are arranged between a housing 121 of the second arm part 12 and the first rotation shaft 41 in the radial direction.

Also, in the first embodiment, a size of the second bearing 44 that is arranged in the lower part of the second rotation shaft 43 is smaller than the second bearing 44 that is arranged in the upper part of the second rotation shaft 43. Specifically, sizes in the height and radial directions of the second bearing 44 that is arranged in the lower part of the second rotation shaft 43 is smaller than the second bearing 44 that is arranged in the upper part of the second rotation shaft 43. Also, a diameter of the part of the second rotation shaft 43 on which the upper second bearing 44 is arranged is larger than a diameter the part on which the lower second bearing 44 is arranged. Specifically, a diameter of a part of the second rotation shaft 43 that is arranged upward with respect to the first rotation shaft 41 is larger than a part of the second rotation shaft that overlaps the first rotation shaft 41 as viewed the radial direction. Here, the two first bearings 42 have the same size.

Also, in the first embodiment, the wrist joint JT3 includes hand drive mechanisms 50. The hand drive mechanisms 50 and the first bearings 42 are arranged to overlap each other as viewed in a Y direction, which is a horizontal direction. Specifically, the hand drive mechanisms 50 and the lower first bearing 42 of the two first bearings 42 are arranged to overlap each other as viewed in the Y direction, which is the horizontal direction. Also, the Y direction is a longitudinal direction of the second arm part 12.

Two hand drive mechanisms 50 are provided corresponding to the first substrate-holding hand 21 and the second substrate-holding hand 22. In FIGS. 2 and 3, one of the two hand drive mechanisms 50 is entirely illustrated, and another of the two hand drive mechanisms 50 is illustrated by only a part of the gear 521, which will be described later, for ease of illustration. The two hand drive mechanisms 50 have basically a similar configuration except that the hand to be driven by them are different. For this reason, one of the two hand drive mechanisms 50 is described in detail.

The hand drive mechanism 50 includes an electric motor 51 and a power transmitter 52. The electric motor 51 is a driving source for driving the second substrate-holding hand 22. The power transmitter 52 transmits a driving force from the electric motor 51 to the second rotation shaft 43. The power transmitter 52 has a plurality of gears including the gear 521. The gear 521 is connected to a gear 53 that includes whose output side is arranged coaxially with the second rotation shaft 43. The gear 53 is securely fastened to the second rotation shaft 43 to rotate together with the second rotation shaft 43. When the gear 53 is rotated, the second rotation shaft 43 is rotated.

Here, the gear 521 of another hand drive mechanism 50 is connected to a gear part 411 whose output side is formed integrally with a lower part of the first rotation shaft 41. When the gear part 411 is rotated, the first rotation shaft 41 is rotated.

Also, the second arm part 12 includes a housing part 122, which is arranged as a thinner part arranged under the hand drive mechanisms 50 and the wrist joint JT3. Accordingly, because the hand drive mechanisms 50 and the wrist joint JT3 can be arranged at lower positions relative to a housing part that is not the thinner part, the first substrate-holding hand 21 and the second substrate-holding hand 22 can be correspondingly arranged at lower positions. Consequently, it is possible to reduce increase of a size of the substrate-conveying robot 100 in the height direction. The second arm part 12 includes the housing part 122, and a housing part 123 that is connected to the housing part 122 and arranged on the first arm part 11 side with respect to the housing part 122. The housing part 122 is formed thinner than the housing part 123 in the Z direction, which is the height direction.

### (Shoulder and Elbow Joints)

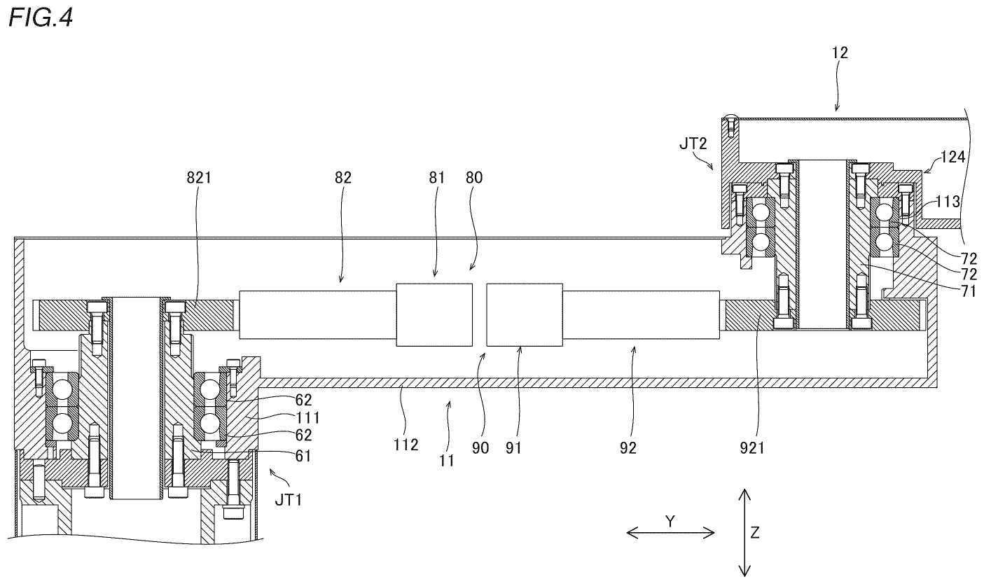

Also, in the first embodiment, as shown in FIGS. 2 and 4, the shoulder joint JT1 includes third bearings 62 rotatably supporting a third rotation shaft 61 for rotating the first arm part 11. The elbow joint JT2 includes fourth bearings 72 rotatably supporting the fourth rotation shaft 71 for rotating the second arm part 12. The third bearing 62 and the fourth bearing 72 are ball bearings. Specifically, the third bearings 62 are two angular contact ball bearings, and the fourth bearings 72 are two angular contact ball bearings. Each of the third bearings 62 and the fourth bearings 72 includes balls as rolling elements, a retainer retaining the balls, an outer race, and an inner race. The balls are retained in the retainer to be positioned without deflection. The fourth rotation shaft 71 is an example of an arm rotation shaft. The fourth bearings 72 are examples of an arm part rotation shaft bearing.

Also, the two third bearings 62 are arranged on the third rotation shaft 61. The two third bearings 62 are arranged adjacent to each other in the Z direction, which is the height direction. In the two third bearings 62, the upper third bearing 62 bears an axial load in one axial direction, and the lower third bearing 62 bears an axial load in another axial direction. Also, the two third bearings 62 are arranged between a housing part 111 of the first arm part 11 and the third rotation shaft 61 in the radial direction. Also, the two third bearings 62 have the same size.

Also, in the first embodiment, the third bearings 62 are arranged to least partially protrude downward with respect to a part 112 of the first arm part 11 that extends in the Y direction, which is the horizontal direction. Specifically, in the two third bearings 62, a part of the upper third bearing 62 and the entire lower third bearing 62 are arranged to protrude downward with respect to the part 112. Also, a part of the third rotation shaft 61 that is located downward from and including a part that overlaps the third bearings 62 is arranged to protrude downward with respect to the part 112. The part 112 is a lower housing part of the first arm part 11. Also, the Y direction is a longitudinal direction of the first arm part 11.

Also, the two fourth bearings 72 are arranged on the fourth rotation shaft 71. The two fourth bearings 72 are arranged adjacent to each other in the Z direction, which is the height direction. In the two fourth bearings 72, the upper fourth bearing 72 bears an axial load in one axial direction, and the lower fourth bearing 72 bears an axial load in another axial direction. Also, the two fourth bearings 72 are arranged between a housing part 113 of the first arm part 11 and the fourth rotation shaft 71 in the radial direction. Also, the two fourth bearings 72 have the same size.

In the first embodiment, the fourth bearings 72 are arranged astride the first arm part 11 and the second arm part 12 in the Z direction, which is the height direction. In other words, the fourth bearings 72 are arranged to overlap the first arm part 11 and the second arm part 12 in the Y direction, which is the horizontal direction. Also, the second arm part 12 is connected to the first arm part 11 in the elbow joint JT2 to partially cover the first arm part 11 from upper and lateral sides of the first arm part. Specifically, the second arm part 12 has a recessed part 124 that covers the housing part 113, which protrudes upward, and from the upper and lateral sides of the housing part. The recessed part 124 is retracted upward. Also, the recessed part 124 has a lateral side wall, which extends in the Z direction, which is in the height direction, and is arranged adjacent to the housing part 113 in the Y direction, which is in the horizontal direction.

Also, the shoulder joint JT1 includes a first arm drive mechanism 80. The first arm drive mechanism 80 includes an electric motor 81 and a power transmitter 82. The electric motor 81 is a driving source for driving the first arm part 11. The power transmitter 82 transmits a driving force from the electric motor 81 to the third rotation shaft 61. The power transmitter 82 has a plurality of gears including the gear 821. The gear 821 is arranged coaxially with the third rotation shaft 61, and is securely fastened to the third rotation shaft 61 to rotate together with the third rotation shaft 61. When the gear 821 is rotated, the third rotation shaft 61 is rotated.

Also, the elbow joint JT2 includes a second arm drive mechanism 90. The second arm drive mechanism 90 includes an electric motor 91 and a power transmitter 92. The electric motor 91 is a driving source for driving the second arm part 12. The power transmitter 92 transmits a driving force from the electric motor 91 to the fourth rotation shaft 71. The power transmitter 92 has a plurality of gears including the gear 921. The gear 921 is arranged coaxially with the fourth rotation shaft 71, and is securely fastened to the fourth rotation shaft 71 to rotate together with the fourth rotation shaft 71. When the gear 921 is rotated, the fourth rotation shaft 71 is rotated.

### Advantages of First Embodiment

In the first embodiment, as described above, a substrate-conveying robot 100 includes a horizontal multi-joint robot arm 10; and a substrate-holding hand 20 arranged in a distal end part of the robot arm 10, wherein the substrate-holding hand 20 includes a first substrate-holding hand 21, and a second substrate-holding hand 22 arranged on or above the first substrate-holding hand 21 and operating independently of the first substrate-holding hand 21, the robot arm 10 includes a wrist joint JT3 for driving the first substrate-holding hand 21 and the second substrate-holding hand 22, the wrist joint JT3 includes first bearings 42 rotatably supporting a first rotation shaft 41 for rotating the first substrate-holding hand 21, and second bearings 44 rotatably supporting a second rotation shaft 43 for rotating the second substrate-holding hand 22, and the first bearings 42 and the second bearings 44 are ball bearings.

According to this configuration, dissimilar to a case in which cross roller bearings are used as the first bearings 42 and the second bearings 44, because spherical balls can be used as rolling elements instead of cylindrical rolling elements, it is possible to prevent that wobbling of deflections of the rollers causes fluctuation of friction of the bearings and fluctuation of a rotation amount of the wrist joint JT3. Consequently, positioning accuracy of repeated operations can be improved by preventing fluctuation of a position of each repeated operation of the substrate-conveying robot 100.

In the first embodiment, as described above, a substrate-conveying robot 100 includes a horizontal multi-joint robot arm 10; and a substrate-holding hand 20 arranged in a distal end part of the robot arm 10, wherein the robot arm 10 includes a first arm part 11, a second arm part 12 including one end connected to the first arm part 11 and another end to which the substrate-holding hand 20 is connected, and an elbow joint JT2 for driving the second arm part 12, the elbow joint JT2 includes fourth bearings 72 rotatably supporting a fourth rotation shaft 71 for rotating the second arm part 12, and the fourth bearings 72 are arranged astride the first arm part 11 and the second arm part 12 in a height direction.

According to this configuration, dissimilar to a case in which the fourth rotation shaft 71 bearings are arranged in the first arm part 11 or the second arm part 12, because the first arm part 11 or the second arm part 12 does not necessarily have a height that can accommodate the entire fourth bearings 72, it is possible to reduce increase of a size of the first arm part 11 or the second arm part 12 in the height direction. Consequently, it is possible to reduce increase of a size of the substrate-conveying robot 100 in the height direction. Here, the prevention of increase of a size of the substrate-conveying robot 100 in the height direction is particularly effective in a case in which ball bearings, which tend to be thicker in the height direction as compared to cross roller bearings, are used.

In the first embodiment, as described above, the first bearings 42 are two angular contact ball bearings, and the second bearings 44 are two angular contact ball bearings. Accordingly, because axial loads in both axial directions can be properly borne by the two angular contact ball bearings, it is possible to improve positioning accuracy of repeated operations while properly bearing axial loads in both axial directions.

In the first embodiment, as discussed above, the second rotation shaft 43 is arranged inward of the first rotation shaft 41 in a radial direction, and extends upward with respect to the first rotation shaft 41; the two second bearings 44 are arranged in upper and lower parts of the second rotation shaft 43; and the two first bearings 42 are arranged on the first rotation shaft 41 between the two second bearings 44. Accordingly, the second rotation shaft 43 can be easily supported by the two second bearings 44, and the first rotation shaft 41 can be easily supported by the two first bearings 42.

In the first embodiment, as discussed above, a size in the height direction of the second bearing 44 that is arranged in the lower part of the second rotation shaft 43 is smaller than the second bearing 44 that is arranged in the upper part of the second rotation shaft 43. Accordingly, even in a case in which arrangement of two first bearings 42 and two second bearings 44 tends to increase the size in the height direction of the substrate-conveying robot 100, it is possible to reduce increase of a size of the substrate-conveying robot 100 in the height direction to a minimum.

In the first embodiment, as discussed above, the wrist joint JT3 includes hand drive mechanisms 50, and the hand drive mechanisms 50 and the first bearings 42 are arranged to overlap each other as viewed in a horizontal direction. Accordingly, as compared with a case in which the hand drive mechanisms 50 and the first bearings 42 are arranged not to overlap each other as viewed in a horizontal direction, it is possible to reduce increase of a size of the robot arm 10 in the height direction. Consequently, it is possible to reduce increase of a size of the substrate-conveying robot 100 in the height direction. Here, the prevention of increase of a size of the substrate-conveying robot 100 in the height direction is particularly effective in a case in which ball bearings, which tend to be thicker in the height direction as compared to cross roller bearings, are used.

In the first embodiment, as discussed above, the robot arm 10 further includes a first arm part 11, a second arm part 12 including one end connected to the first arm part 11 and another end to which the first substrate-holding hand 21 and the second substrate-holding hand 22 are connected, a shoulder joint JT1 for driving the first arm part 11, an elbow joint JT2 for driving the second arm part 12; the shoulder joint JT1 includes third bearings 62 rotatably supporting a third rotation shaft 61 for rotating the first arm part 11; the elbow joint JT2 includes fourth bearings 72 rotatably supporting the fourth rotation shaft 71 for rotating the second arm part 12; and the first bearings 42, the second bearings 44, the third bearings 62 and the fourth bearings 72 are ball bearings. Accordingly, not only in the wrist joint JT3 but also in the shoulder joint JT1 and the elbow joint JT2, it is possible to prevent that wobbling of deflections of rollers causes fluctuation of friction of the bearings and fluctuations of rotation amounts of the shoulder joint JT1 and the elbow joint JT2. Consequently, positioning accuracy of repeated operations can be further improved by preventing fluctuation of a position of each repeated operation of the substrate-conveying robot 100.

In the first embodiment, as described above, the first bearings 42, the second bearings 44, the third bearings 62 and the fourth bearings 72 are angular contact ball bearings. Accordingly, the first bearings 42, the second bearings 44, the third bearings 62 and the fourth bearings 72 can be constructed of angular contact ball bearings, which are suitable for highly accurate operations.

In the first embodiment, as described above, the third bearings 62 are arranged to least partially protrude downward with respect to a part of the first arm part 11 that extends in the horizontal direction. Accordingly, as compared with a case in which the third bearings 62 are arranged upward with respect to the part of the first arm part 11 that extends in the horizontal, it is possible to reduce increase of a size of the first arm part 11. Consequently, it is possible to reduce increase of a size of the substrate-conveying robot 100 in the height direction.

In the first embodiment, as described above, the second arm part 12 is connected to the first arm part 11 in the elbow joint JT2 to partially cover the first arm part 11 from upper and lateral sides of the first arm part. Accordingly, because the fourth bearings 72 can be easily arranged astride the first arm part 11 and the second arm part 12 in the height direction, it is possible to easily reduce increase of a size of the first arm part 11 or the second arm part 12 in the height direction. Also, because the second arm part 12 partially covers the first arm part 11 from the upper and lateral sides of the first arm part, the second arm part 12 can increase rigidity of a connection part between the second arm part and the first arm part 11. Consequently, it is possible to easily reduce increase of a size of the first arm part 11 or the second arm part 12 in the height direction while increasing rigidity of the connection part between the second arm part 12 and the first arm part 11 by using the second arm part.

### Second Embodiment

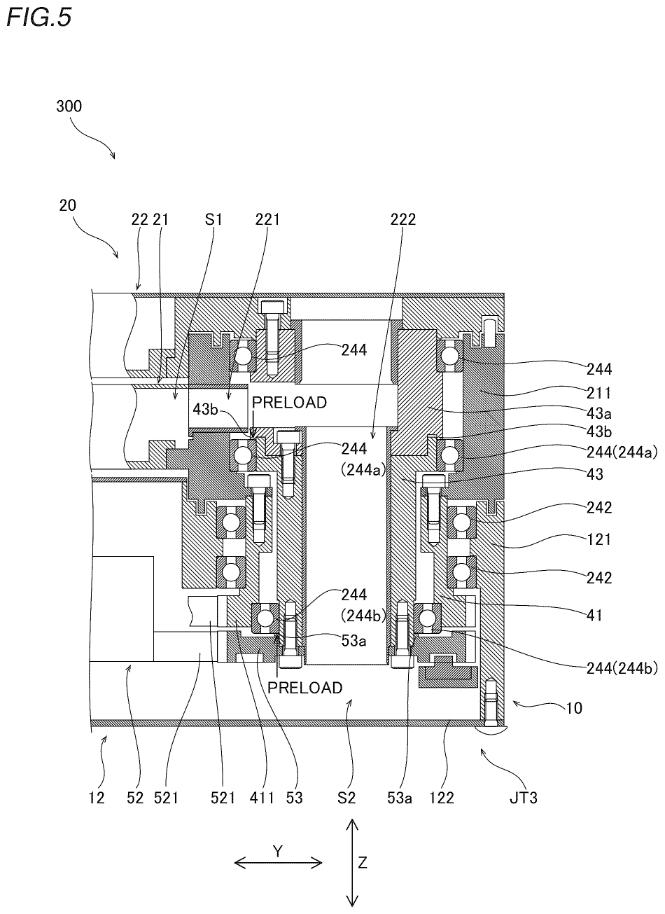

The following description describes a configuration of a substrate-conveying robot 300 according to a second embodiment with reference to FIG. 5. The same configurations as those of the first embodiment are denoted by the same reference numerals, and their description is omitted.

As shown in FIG. 5, the wrist joint JT3 of the substrate-conveying robot 300 according to the second embodiment includes first bearings 242 rotatably supporting the first rotation shaft 41 for rotating the first substrate-holding hand 21, and second bearings 244 rotatably supporting the second rotation shaft 43 for rotating the second substrate-holding hand 22 instead of the first bearings 42 and the second rotation shaft 44 according to the first embodiment. The first bearing 242 and the second bearing 244 are ball bearings. Specifically, the first bearings 242 are two deep groove ball bearings. The second bearings 244 are three deep groove ball bearings. Each of the first bearings 242 and the second bearings 244 includes balls as rolling elements, a retainer retaining the balls, an outer race, and an inner race. The balls are retained in the retainer to be positioned without deflection.

Two of the three second bearings 244 are arranged on an upper side part of the second rotation shaft 43, and another is arranged on a lower side part. The three second bearings 244 are spaced away from each other in the Z direction, which is the height direction. Also, the upper two second bearings 244 are arranged between the housing part 211 of the first substrate-holding hand 21 and the second rotation shaft 43 in a radial direction. Also, the lower one second bearing 244 is arranged between the first rotation shaft 41 and the second rotation shaft 43 in the radial direction.

Also, the two first bearings 242 are arranged on the first rotation shaft 41 between the two second bearings 244. The two first bearings 242 are arranged adjacent to each other in the Z direction, which is the height direction. Also, the two first bearings 242 are arranged between the housing 121 of the second arm part 12 and the first rotation shaft 41 in the radial direction.

Here, in the second embodiment, two of the three second bearings 244 are arranged downward with respect to a through hole 221 that connects a hand space S1 in the first substrate-holding hand 21 to an arm space S2 in the second robot arm part 12 of the robot arm 10, and preloads are applied to the two second bearings, which are arranged downward with respect to the through hole 221. Also, the another second bearing 244 in the three second bearings 244 is further arranged upward with respect to the through hole 221. Here, the second bearing 244 on an upper side in the two second bearings 244 that are arranged downward with respect to the through hole 221 is referred to as a second bearing 244a, and another second bearing 244 on a lower side is referred to as a second bearing 244b for ease of explanation.

A preload is applied to the second bearing 244a in one axial direction by a larger diameter part 43a of the second rotation shaft 43. The larger diameter part 43a of the second rotation shaft 43 includes a preload part 43b for pressing the second bearing 244a in the one axial direction. The preload part 43b is a protrusion that protrudes downward. The preload is applied to the second bearing 244a by pressing the second bearing 244a downward by using the preload part 43b. Here, the second bearing 244a can also be called a preload bearing.

A preload is applied to the second bearing 244b in the another axial direction by the gear 53. The gear 53 includes a preload part 53a for pressing the second bearing 244b in the another axial direction. The preload part 53a is a protrusion that protrudes upward. The preload is applied to the second bearing 244b by pressing the second bearing 244b upward by using the preload part 53a. Note that only one preload position of each of the second bearing 244a and the second bearing 244b is shown in FIG. 5 for ease of illustration.

The preloads are applied to the second bearing 244a and the second bearing 244b in the axial directions opposite to each other.

The through-hole 221 is provided to receive wires including the sensor wires of the first substrate-holding hand 21, and the like. The through hole 221 is connected to a through hole 222 provided in the second rotation shaft 43. The through hole 221 connects the hand space S1 to the arm space S2 through the through hole 222. The through hole 221 is formed to extend in the horizontal direction from the first substrate-holding hand 21 to the through hole 222 of the second rotation shaft 43. The through hole 222 is formed to extend in the axial direction. The wires of the first substrate-holding hand 21 are routed from the hand space S1 to the arm space S2 through the through hole 221 and the through hole 222. The other configuration of the second embodiment is similar to the first embodiment.

### Advantages of Second Embodiment

In the second embodiment, the following advantages are obtained.

In the second embodiment, as described above, the first bearings 242 and the second bearings 244 are ball bearings. Accordingly, similar to the aforementioned first embodiment, it is possible to improve positioning accuracy of repeated operations.

In the second embodiment, as described above, the two second bearings 244a and 244b are arranged downward with respect to the through hole 221 that connects the hand space S1 in the first substrate-holding hand 21 to the arm space S2 in the robot arm 10, and preloads are applied to the two second bearings, which are arranged downward with respect to the through hole 221. Accordingly, dissimilar to a case in which preloads are applied to two second bearings 244a and 244b that are arranged to interpose the through hole 221 between them, it is possible to prevent loads that are applied the through hole 221 by the preloaded, and to prevent reduction of the preload applied to the bearings due to relief of the preloads caused by the through hole 221.

In the second embodiment, the second bearing 244 is further arranged upward with respect to the through hole 221. Accordingly, the second rotation shaft 43 can be reliably rotatably supported by the second bearing 244 that is arranged upward with respect to the through hole 221, and the two second bearings 244 that are arranged downward with respect to the through hole 221.

The other advantages of the second embodiment are similar to the first embodiment.

### Modified Embodiments

Note that the embodiment disclosed this time must be considered as illustrative in all points and not restrictive. The scope of the present disclosure is not shown by the above description of the embodiments but by the scope of claims for patent, and all modifications (modified embodiments) within the meaning and scope equivalent to the scope of claims for patent are further included.

While the example in which the substrate-conveying robot includes two substrate-holding hands has been shown in the aforementioned first and second embodiments, the present disclosure is not limited to this. The substrate-conveying robot may include one substrate-holding hand, or three or more substrate-holding hands.

While the example in the first bearings and the second bearings are angular contact ball bearings has been shown in the aforementioned first embodiment, and the example in the first bearings and the second bearings are deep groove ball bearings has been shown in the aforementioned second embodiment, the present disclosure is not limited to these. The first bearings and the second bearings may be ball bearings other than angular contact ball bearings and deep groove ball bearings.

While the example in the third bearings and the fourth bearings are angular contact ball bearings has been shown in the aforementioned first and second embodiments, the present disclosure is not limited to this. The third bearings and the fourth bearings may be ball bearings other than angular contact ball bearings, such as deep groove ball bearings. Also, the first bearings, the second bearings, the third bearings and the fourth bearings are not necessarily the same type of ball bearings, but some of the first bearings, the second bearings, the third bearings and the fourth bearings may be a different type of ball bearing from other bearings. Also, the third bearings and the fourth bearings may be cross roller bearings, or the like.

While the example in which a size in height direction of the second bearing that is arranged in the lower part of the second rotation shaft is smaller than the second bearing that is arranged in the upper part of the second rotation shaft has been shown in the aforementioned first embodiment, the present disclosure is not limited to this. A size in height direction of the second bearing that is arranged in the upper part of the second rotation shaft is smaller than the second bearing that is arranged in the lower part of the second rotation shaft. Also, the two second bearings may have the same size.

While the example in which the hand drive mechanism and the second bearings are arranged to overlap each other as viewed in a horizontal direction has been shown in the aforementioned first and second embodiments, the present disclosure is not limited to this. The hand drive mechanism and the second bearings may be are arranged not to overlap each other as viewed in the horizontal direction.

While the example in which the robot arm includes two arm parts has been shown in the aforementioned first and second embodiments, the present disclosure is not limited to this. The robot arm may include three or more arm parts.

While the example in which the fourth bearings are arranged astride the first arm part and the second arm part in a height direction has been shown in the aforementioned first and second embodiments, the present disclosure is not limited to this. The entire fourth bearings may be arranged in the first arm or the second arm.

While the example in which the third bearings are arranged to partially protrude downward with respect to a part of the first arm part that extends in a horizontal direction has been shown in the aforementioned first and second embodiments, the present disclosure is not limited to this. The entire third bearing may be arranged to protrude downward with respect to the part of the first arm part that extends in the horizontal direction. Also, the entire third bearing may be arranged not to protrude downward with respect to the part of the first arm part that extends in the horizontal direction.

While the example in which the substrate-conveying robot is a vacuum robot arranged in a vacuum environment has been shown in the aforementioned the aforementioned first and second embodiments, the present disclosure is not limited to this. The substrate-conveying robot may be an atmospheric robot arranged in an atmospheric environment.

While the example in which two second bearings are arranged downward with respect to the through hole, and one second bearing is arranged upward with respect to the through hole has been shown in the aforementioned second embodiment, the present disclosure is not limited to this. For example, the second bearing may not be arranged upward with respect to the through hole, and preloads may be applied to two second bearings that are arranged downward with respect to the through hole.

### DESCRIPTION OF REFERENCE NUMERALS

10; robot arm
11; first arm part
12; second arm part
20; substrate-holding hand
21; first substrate-holding hand
22; second substrate-holding hand
41; first rotation shaft
42, 242; first bearing
43; second rotation shaft
44, 244, 244a, 244b; second bearing
50; hand drive mechanism
61; third rotation shaft
62; third bearing
71; fourth rotation shaft (arm part rotation shaft)
72; fourth bearing (arm part rotation shaft bearing)
100, 300; substrate-conveying robot
112; part of first arm part that extends in
horizontal direction
221; through hole
JT1; shoulder joint (first joint)
JT2; elbow joint (second joint, arm part joint)
JT3; wrist joint
S1; hand space
S2; arm space

1. A substrate-conveying robot comprising:
a horizontal multi-joint robot arm; and
a substrate-holding hand arranged in a distal end part of the robot arm, wherein
the substrate-holding hand includes a first substrate-holding hand, and a second substrate-holding hand arranged on or above the first substrate-holding hand and operating independently of the first substrate-holding hand,
the robot arm includes a wrist joint for driving the first substrate-holding hand and the second substrate-holding hand,
the wrist joint includes a first bearing(s) rotatably supporting a first rotation shaft for rotating the first substrate-holding hand, and a second bearing(s) rotatably supporting a second rotation shaft for rotating the second substrate-holding hand, and
the first bearing(s) and the second bearing(s) are ball bearings.

2. The substrate-conveying robot according to claim 1, wherein the first bearings are two angular contact ball bearings, and the second bearings are two angular contact ball bearings.

3. The substrate-conveying robot according to claim 2, wherein
the second rotation shaft is arranged inward of the first rotation shaft in a radial direction, and extends upward with respect to the first rotation shaft;
the two second bearings are arranged in upper and lower parts of the second rotation shaft; and
the two first bearings are arranged on the first rotation shaft between the two second bearings.

4. The substrate-conveying robot according to claim 3, wherein a size in height direction of the second bearing that is arranged in the lower part of the second rotation shaft is smaller than the second bearing that is arranged in the upper part of the second rotation shaft.

5. The substrate-conveying robot according to claim 1, wherein
the wrist joint includes a hand drive mechanism; and
the hand drive mechanism and the first bearing(s) are arranged to overlap each other as viewed in a horizontal direction.

6. The substrate-conveying robot according to claim 1, wherein
the robot arm further includes a first arm part, a second arm part including one end connected to the first arm part and another end to which the first substrate-holding hand and the second substrate-holding hand are connected, a first joint for driving the first arm part, and a second joint for driving the second arm part;
the first joint includes a third bearing(s) rotatably supporting a third rotation shaft for rotating the first arm part;
the second joint includes a fourth bearing(s) rotatably supporting a fourth rotation shaft for rotating the second arm part; and
the first bearing(s), the second bearing(s), the third bearing(s), and the fourth bearing(s) are ball bearings.

7. The substrate-conveying robot according to claim 6, wherein the first bearing(s), the second bearing(s), the third bearing(s), and the fourth bearing(s) are angular contact ball bearings.

8. The substrate-conveying robot according to claim 6, wherein the fourth bearing(s) is/are arranged astride the first arm part and the second arm part in a height direction.

9. The substrate-conveying robot according to claim 6, wherein the third bearing(s) is/are arranged to least partially protrude downward with respect to a part of the first arm part that extends in a horizontal direction.

10. The substrate-conveying robot according to claim 1, wherein two second bearings as the second bearings are arranged downward with respect to a through hole that connects a hand space in the first substrate-holding hand to an arm space in the robot arm, and preloads are applied to the two second bearings, which are arranged downward with respect to the through hole.

11. The substrate-conveying robot according to claim 10, wherein the second bearings further include a second bearing that is arranged upward with respect to the through hole.

12. A substrate-conveying robot comprising:
a horizontal multi-joint robot arm; and
a substrate-holding hand arranged in a distal end part of the robot arm, wherein
the robot arm includes a first arm part, a second arm part including one end connected to the first arm part and another end to which the substrate-holding hand is connected, and an arm part joint for driving the second arm part,
the arm part joint includes an arm part rotation shaft bearing(s) rotatably supporting an arm part rotation shaft for rotating the second arm part, and
the arm part rotation shaft bearing(s) is/are arranged astride the first arm part and the second arm part in a height direction.

13. The substrate-conveying robot according to claim 12, wherein the second arm part is connected to the first arm part in the arm part joint to partially cover the first arm part from upper and lateral sides of the first arm part.

14. The substrate-conveying robot according to claim 12, wherein the arm part rotation shaft bearing(s) is/are a ball bearing(s).
